(19) United States
(12) Patent Application Publication
(10) Pub. No.: US 2023/0050841 A1
(43) Pub. Date: Feb. 16, 2023

(54) CONFIGURABLE BIAS SUPPLY WITH BIDIRECTIONAL SWITCH

(71) Applicant: Advanced Energy Industries, Inc., Fort Collins, CO (US)

(72) Inventor: Hien Minh Nguyen, Longmont, CO (US)

(21) Appl. No.: 17/401,422

(22) Filed: Aug. 13, 2021

(51) Int. Cl. H01J 37/32; H03K 17/687

(52) U.S. Cl. CPC H01J 37/32174; H03K 17/687; H01J 2237/327

(57) ABSTRACT

Bias supplies, plasma processing systems, and associated methods are disclosed. One bias supply comprises a bidirectional switch configured to enable bidirectional control of current. A controller is configured to control a direction of current through the bidirectional switch over a full current cycle, the full current cycle comprising a first half current cycle and a second half current cycle, the first half current cycle comprising positive current flow, starting from zero current that increases to a positive peak value and then decreases back to zero. The second half current cycle comprises negative current flow, starting from zero current that increases to a negative peak value and then decreases back to zero current to cause an application of the periodic voltage between the output node and the return node.

### BACKGROUND

### Field

The present invention relates generally to power supplies, and more specifically to power supplies for applying a voltage for plasma processing.

### Background

Many types of semiconductor devices are fabricated using plasma-based etching techniques. If it is a conductor that is etched, a negative voltage with respect to ground may be applied to the conductive substrate so as to create a substantially uniform negative voltage across the surface of the substrate conductor, which attracts positively charged ions toward the conductor, and as a consequence, the positive ions that impact the conductor have substantially the same energy.

If the substrate is a dielectric, however, a non-varying voltage is ineffective to place a voltage across the surface of the substrate. But an alternating current (AC) voltage (e.g., high frequency AC or radio frequency (RF)) may be applied to the conductive plate (or chuck) so that the AC field induces a voltage on the surface of the substrate. During the positive peak of the AC cycle, the substrate attracts electrons, which are light relative to the mass of the positive ions; thus, many electrons will be attracted to the surface of the substrate during the positive peak of the cycle. As a consequence, the surface of the substrate will be charged negatively, which causes ions to be attracted toward the negatively-charged surface during the rest of the AC cycle. And when the ions impact the surface of the substrate, the impact dislodges material from the surface of the substrate—effectuating the etching.

In many instances, it is desirable to have a narrow (or specifically tailorable) ion energy distribution, but applying a sinusoidal waveform to the substrate induces a broad distribution of ion energies, which limits the ability of the plasma process to carry out a desired etch profile. Known techniques to achieve a narrow ion energy distribution are expensive, inefficient, difficult to control, and/or may adversely affect the plasma density. As a consequence, many of these known techniques have not been commercially adopted.

Accordingly, a system and method are needed to address the shortfalls of present technology and to provide other new and innovative features.

### SUMMARY

An aspect may be characterized as a bias supply to apply a periodic voltage that comprises an output node, a return node, and a bidirectional switch configured to enable bidirectional control of current between a first node of the bidirectional switch and a second node of the bidirectional switch. A power section is coupled to the output node, the return node, and the first and second nodes of the bidirectional switch, and a controller is configured to control a direction of current through the bidirectional switch over a full current cycle. The full current cycle comprises a first half current cycle and a second half current cycle, the first half current cycle comprising positive current flow, starting from zero current at time t₀, that increases to a positive peak value and then decreases back to zero at a time t₁. The second half current cycle comprises negative current flow, starting from zero current at a time t₂, that increases to a negative peak value and then decreases back to zero current at a time t₃ to cause an application of the periodic voltage between the output node and the return node.

Yet another aspect may be characterized as a plasma processing system that comprises a plasma chamber including a volume to contain a plasma, an input node, and a return node. The plasma processing system also comprises a bidirectional switch configured to enable bidirectional control of current between a first node of the bidirectional switch and a second node of the bidirectional switch. In addition, the plasma processing system comprises means for providing and controlling current through the bidirectional switch over a full current cycle. The full current cycle comprises a first half current cycle and a second half current cycle. The first half current cycle comprises positive current flow, starting from zero current at time t₀, that increases to a positive peak value and then decreases back to zero at a time t₁, and the second half current cycle comprises negative current flow, starting from zero current at a time t₂, that increases to a negative peak value and then decreases back to zero current at a time t₃ to cause an application of a periodic voltage between the output node and the return node.

Another aspect disclosed herein is a non-transitory, tangible processor readable storage medium, encoded with processor readable instructions to control a bidirectional switch of a bias supply. The instructions comprise instructions to provide current through the bidirectional switch and control the current through the bidirectional switch over a full current cycle to cause an application of a periodic voltage between an output node and a return node of the bias supply. The full current cycle comprises a first half current cycle and a second half current cycle. The first half current cycle comprises positive current flow, starting from zero current at time t₀, that increases to a positive peak value and then decreases back to zero at a time t₁. The second half current cycle comprises negative current flow, starting from zero current at a time t₂, that increases to a negative peak value and then decreases back to zero current at a time t₃.

### BRIEF DESCRIPTION OF THE DRAWINGS

FIG. 1 is a block diagram depicting an exemplary plasma processing environment in which bias supplies disclosed herein may be utilized;

FIG. 2 is a schematic diagram depicting an exemplary bias supply;

FIG. 3 is a schematic diagram electrically representing aspects of a plasma processing chamber;

FIGS. 4A, 4B, 4C, and 4D each depict an example of the bias supply depicted in FIG. 2;

FIG. 5 is a flowchart depicting a method that may be traversed in connection with the bias supplies depicted in FIGS. 4A, 4B, 4C, and 4D;

FIGS. 6A, 6B, 6C, and 6D each depict additional examples of bias supplies that may be implemented as the bias supply depicted in FIG. 2;

FIG. 7 is a flowchart depicting a method that may be traversed in connection with the bias supplies depicted in FIGS. 6A, 6B, 6C, and 6D;

FIG. 8A, 8B, and 8C each depict an example of the bidirectional switch depicted in FIGS. 2, 4A, 4B, 4C, 4D, 6A, 6B, 6C, and 6D;

FIG. 9A, 9B, 9C, and 9D are each a timing diagram depicting timing of electrical aspects of the bias supplies described herein when operated with the plasma processing chamber in FIG. 3;

FIG. 10A comprises graphs depicting various examples of periodic voltage waveforms and power associated with each waveform;

FIG. 10B is a graph depicting a sheath voltage that may be produced by each of the periodic voltage waveforms depicted in FIG. 10A;

FIG. 11A comprises graphs depicting various other examples of periodic voltage waveforms and power associated with each waveform;

FIG. 11B is a graph depicting a sheath voltage that may be produced by each of the periodic voltage waveforms depicted in FIG. 11A;

FIG. 12A is a graphical depiction of sheath voltage versus time and a resulting ion flux versus ion energy;

FIG. 12B is a graph of a periodic voltage waveform that may produce the sheath voltage depicted in FIG. 12A;

FIG. 13A depicts another sheath voltage and a resulting ion flux versus ion energy;

FIG. 13B is a graph of a periodic voltage waveform that may produce the sheath voltage depicted in FIG. 13A;

FIG. 14 is a block diagram depicting aspects of a control system; and

FIG. 15 is a block diagram depicting components that may be utilized to implement control aspects disclosed herein.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Preliminary note: the flowcharts and block diagrams in the following Figures illustrate the architecture, functionality, and operation of possible implementations of systems, methods and computer program products according to various embodiments. In this regard, some blocks in these flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

For the purposes of this disclosure, source generators are those whose energy is primarily directed to generating and sustaining the plasma, while “bias supplies” are those whose energy is primarily directed to generating a surface potential for attracting ions and electrons from the plasma.

Described herein are several embodiments of novel bias supplies that may be used to apply a periodic voltage function to a substrate support in a plasma processing chamber.

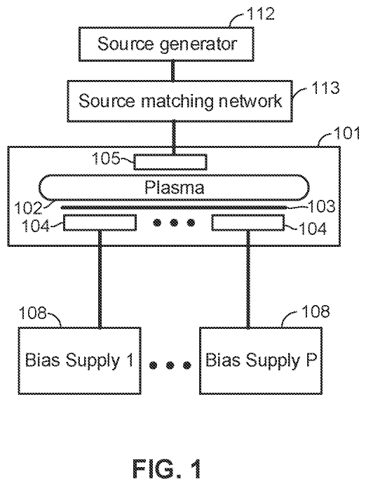

Referring first to FIG. 1, shown is an exemplary plasma processing system (e.g., deposition or etch system) in which bias supplies may be utilized. The plasma processing environment may include many pieces of equipment coupled directly and indirectly to a plasma processing chamber 101, within which a volume containing a plasma 102 and workpiece 103 (e.g., a wafer) and electrodes 104 (which may be embedded in a substrate support) are contained. The equipment may include vacuum handling and gas delivery equipment (not shown), one or more bias supplies 108, one or more source generators 112, and one or more source matching networks 113. In many applications, power from a single source generator 112 is connected to one or multiple source electrodes 105. The source generator 112 may be a higher frequency RF generator (e.g., 13.56 MHz to 120 MHz). The electrode 105 generically represents what may be implemented with an inductively coupled plasma (ICP) source, a dual capacitively-coupled plasma source (CCP) having a secondary top electrode biased at another RF frequency, a helicon plasma source, a microwave plasma source, a magnetron, or some other independently operated source of plasma energy.

In variations of the system depicted in FIG. 1, the source generator 112 and source matching network 113 may be replaced by, or augmented with, a remote plasma source. And other variations of the system may include only a single bias supply 108.

While the following disclosure generally refers to plasma-based wafer processing, implementations can include any substrate processing within a plasma chamber. In some instances, objects other than a substrate can be processed using the systems, methods, and apparatus herein disclosed. In other words, this disclosure applies to plasma processing of any object within a sub-atmospheric plasma processing chamber to affect a surface change, subsurface change, deposition or removal by physical or chemical means.

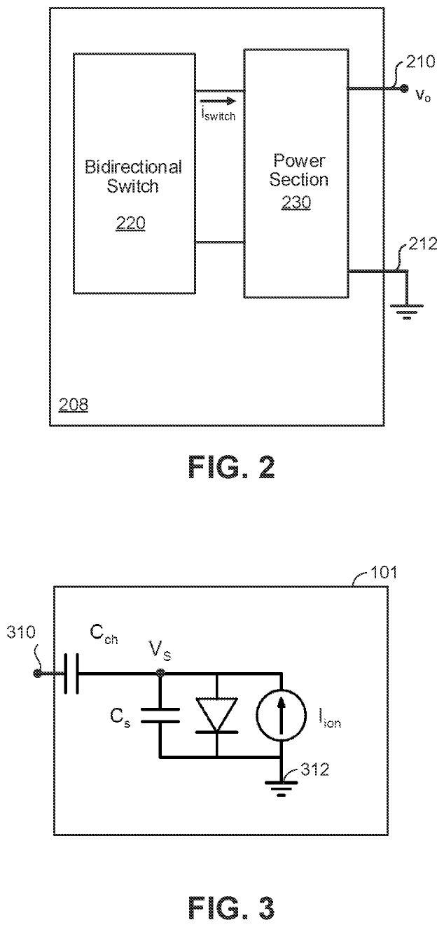

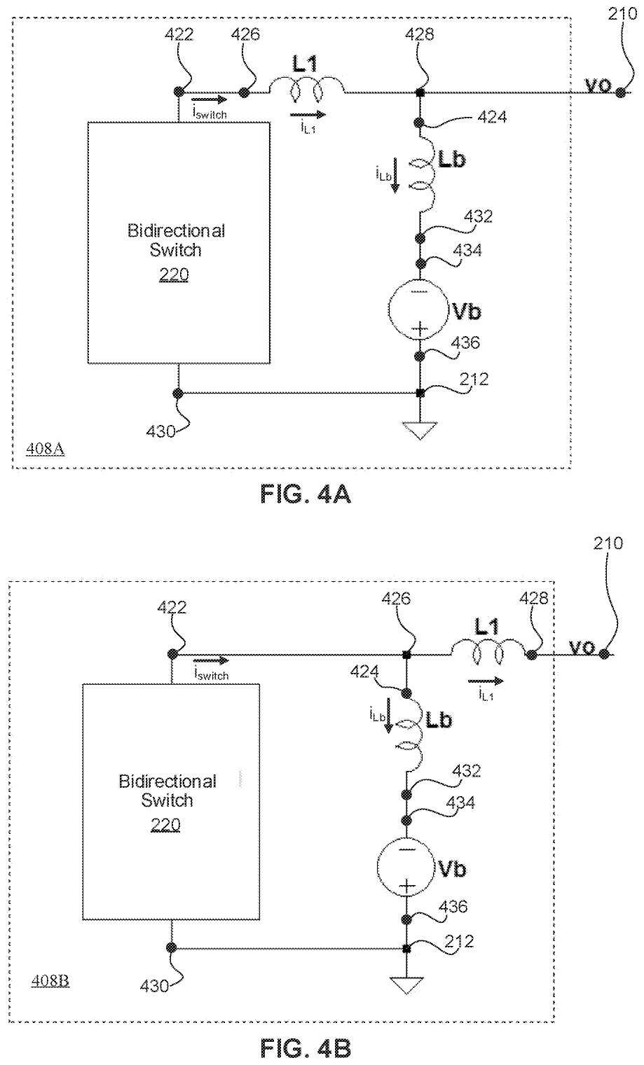

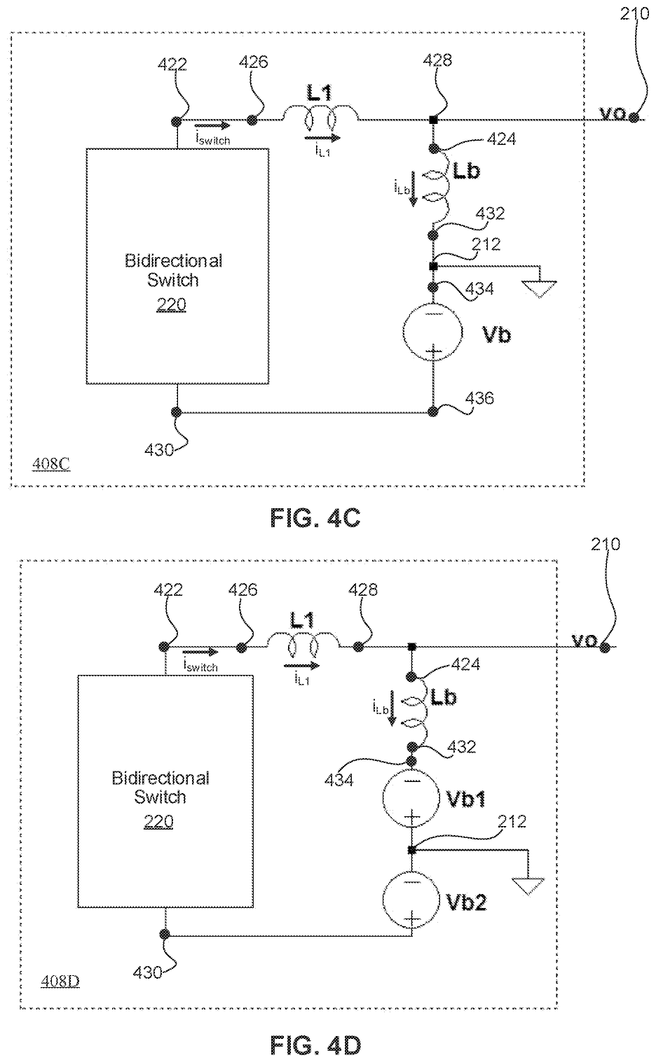

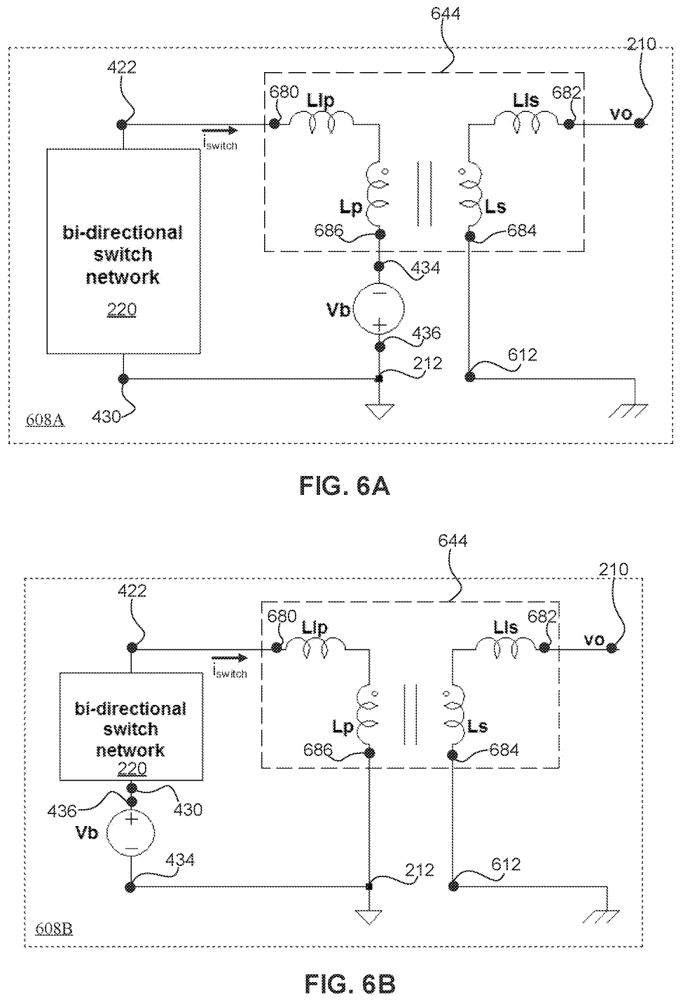

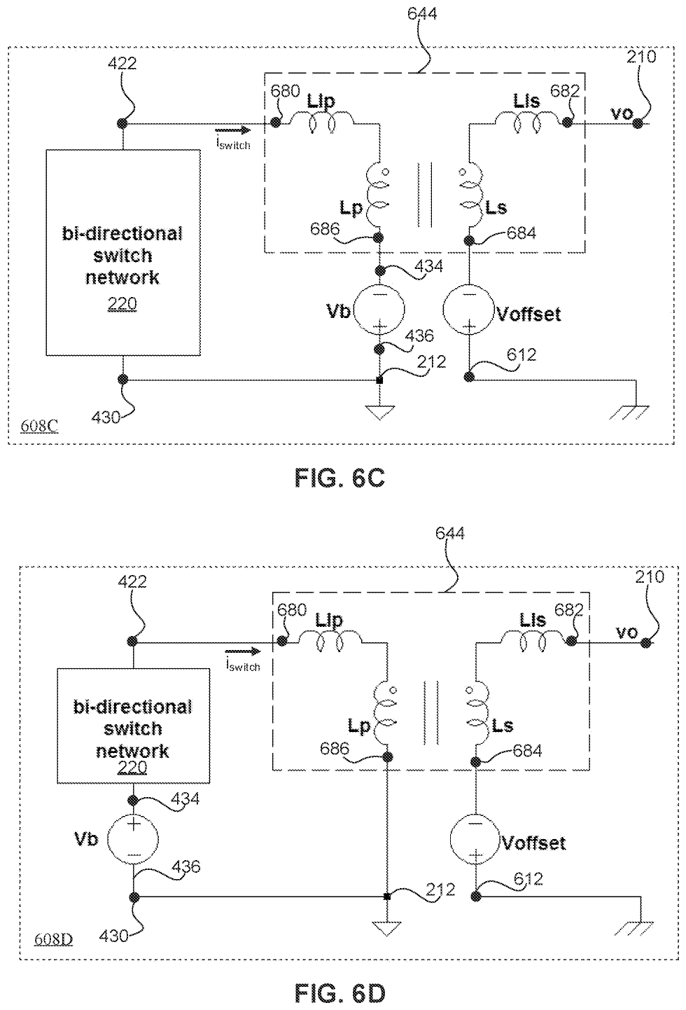

Referring to FIG. 2, shown is an exemplary bias supply 208 that may be utilized to implement the bias supplies 108 described with reference to FIG. 1. The bias supply 208 generally represents many variations of bias supplies described further herein with reference to FIGS. 4A, 4B, 4C, 4D, 6A, 6B, 6C, and 6D to apply a periodic voltage function. Thus, reference to the bias supply 208 generally refers to the bias supply 208 depicted in FIG. 2 and the bias supplies 408A to 408H and 608A to 608D described further herein. As shown, the bias supply 208 includes an output 210 (also referred to as an output node 210), a return node 212, a bidirectional switch 220 and a power section 230. In general, the bias supply 208 generally functions to apply a periodic voltage function between the output node and the return node 212. Current delivered to a load through the output node 210 is returned to the bias supply 208 through the return node 212 that may be common with the load.

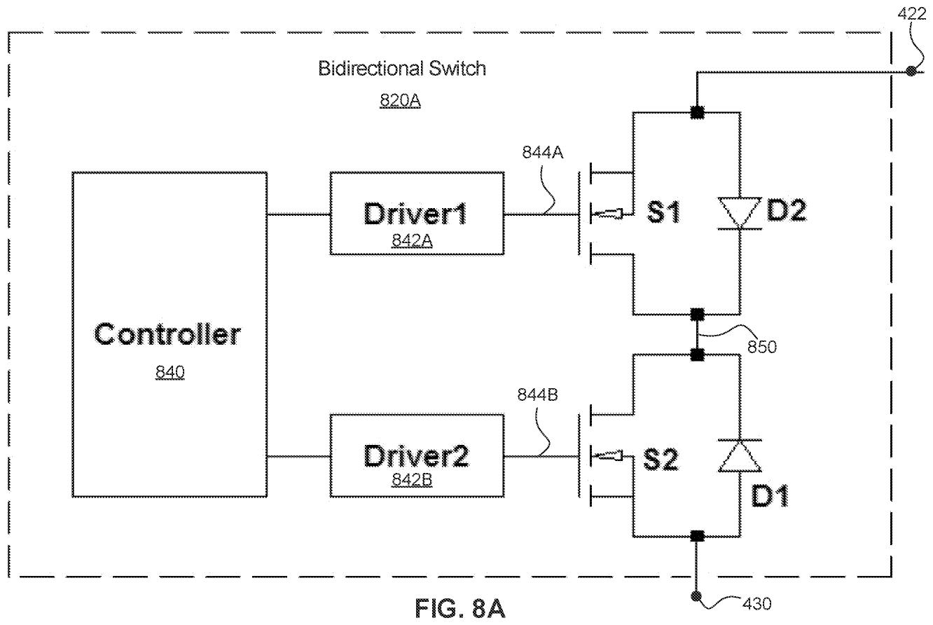

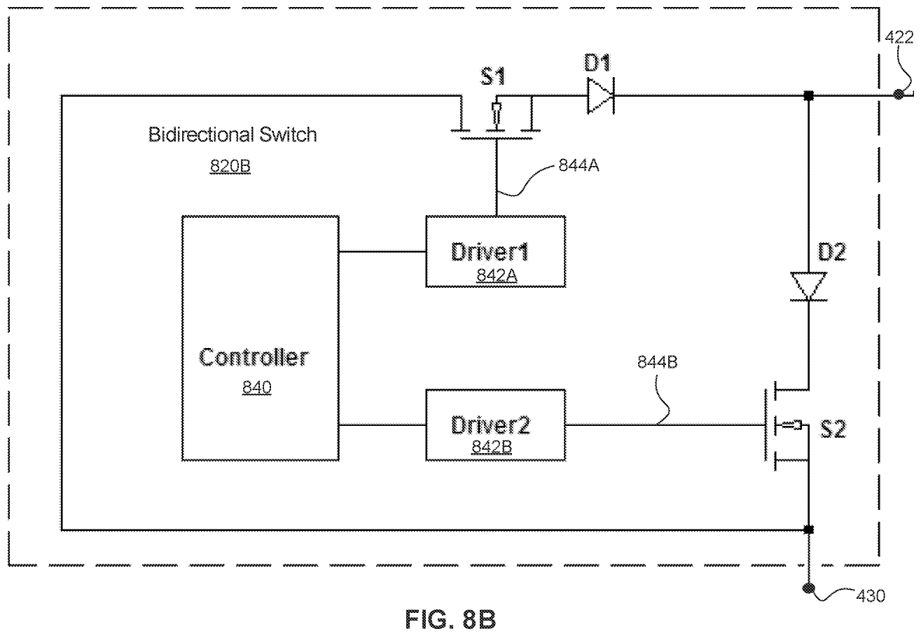

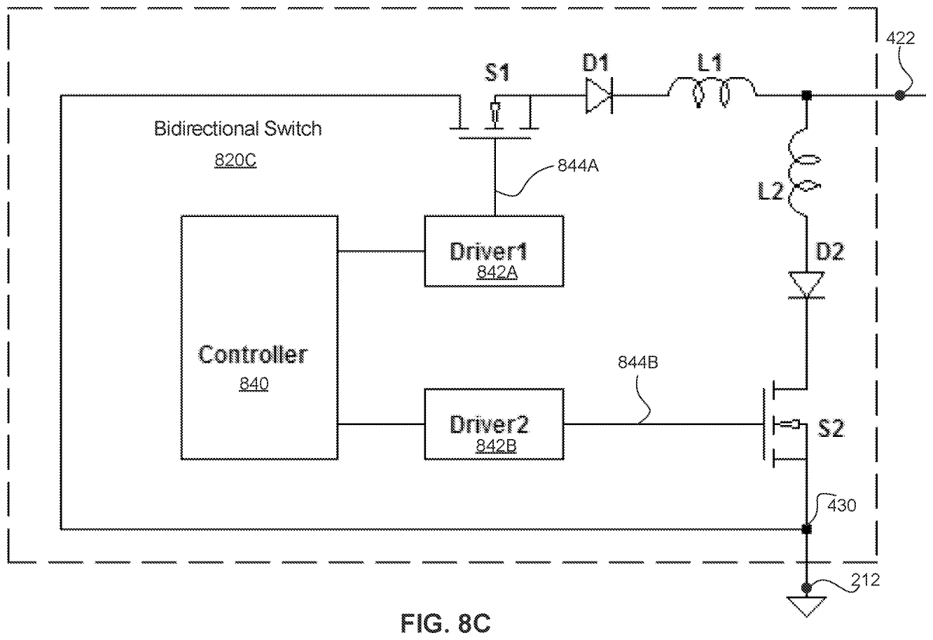

In general, the bidirectional switch enables bidirectional control of current between a first node of the bidirectional switch and a second node of the bidirectional switch. In many implementations, the bidirectional switch 220 is a two-terminal active switch, which can support bidirectional current flow when it is in an on state and bidirectional voltage blocking when it is turned to an off state. In other words, the bidirectional switch 220 is a four-quadrant switch capable of conducting positive or negative ON-state current and capable of blocking positive or negative OFF-state voltage. Examples of the bidirectional switch 220 are provided further herein with reference to FIGS. 8A, 8B, and 8C.

As described further herein, the power section 230 may include a combination of one or more voltage sources and inductive elements, and the bidirectional switch 220 may include switches configured to interoperate with the power section 230. Although not depicted in FIG. 2 for clarity and simplicity, the bias supply 208 may be coupled to a controller and/or include a controller that is coupled to the bidirectional switch 220 and or the power section 230. In many implementations disclosed herein, the controller is configured control a direction of current through the bidirectional switch over a full current cycle that comprises a first half current cycle and a second half current cycle. The first half current cycle comprises positive current flow, starting from zero current that increases to a positive peak value and then decreases back to zero. The second half current cycle comprises negative current flow, starting from zero current, that increases to a negative peak value and then decreases back to zero current to cause an application of the periodic voltage between the output node and the return node.

Referring briefly to FIG. 3, shown is a schematic drawing that electrically depicts aspects of a plasma load within the plasma processing chamber 101. As shown, the plasma processing chamber 101 may be represented by a chuck capacitance C_{ch} (that includes a capacitance of a chuck and workpiece 103) that is positioned between an input node 310 (also referred to as an input node 310) to the plasma processing chamber 101 and a node representing a sheath voltage, Vs, at a surface of the workpiece 103 (also referred to as substrate 103). In addition, a return node 312 (which may be a connection to ground) is depicted. The plasma 102 in the processing chamber is represented by a parallel combination of a sheath capacitance Cs, a diode, and a current source. The diode represents the non-linear, diode-like nature of the plasma sheath that results in rectification of the applied AC field, such that a direct-current (DC) voltage drop, appears between the workpiece 103 and the plasma 102.

Referring to FIGS. 4A, 4B, 4C, and 4D shown are bias supplies 408A, 408B, 408C, and 408D that may be utilized, respectively, to realize the bias supply 208, and hence, bias supplies 408A to 408D may be utilized as the bias supplies 108 depicted in FIG. 1. As shown, each of the bias supplies 408A to 408D comprises a bidirectional switch 220 and one or more voltage sources and inductors arranged in a variety of topologies.

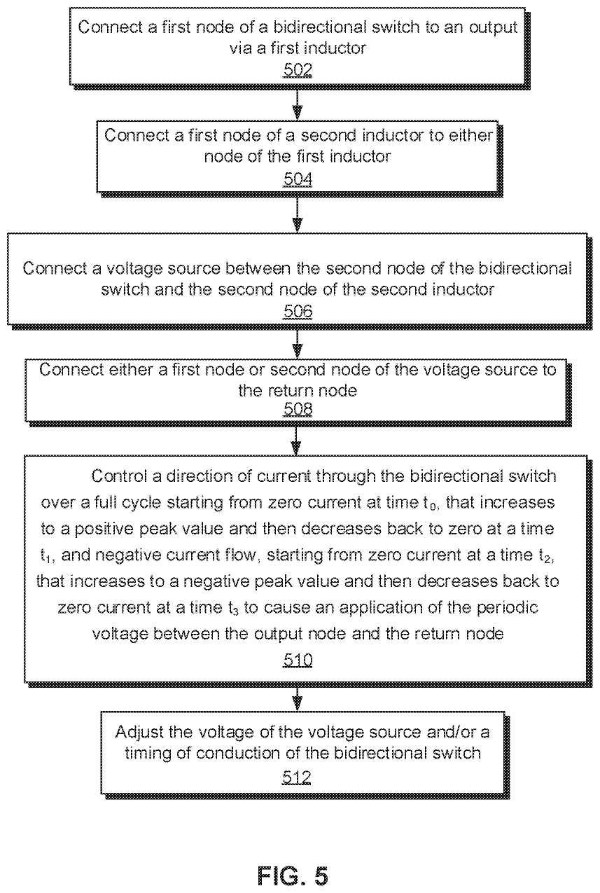

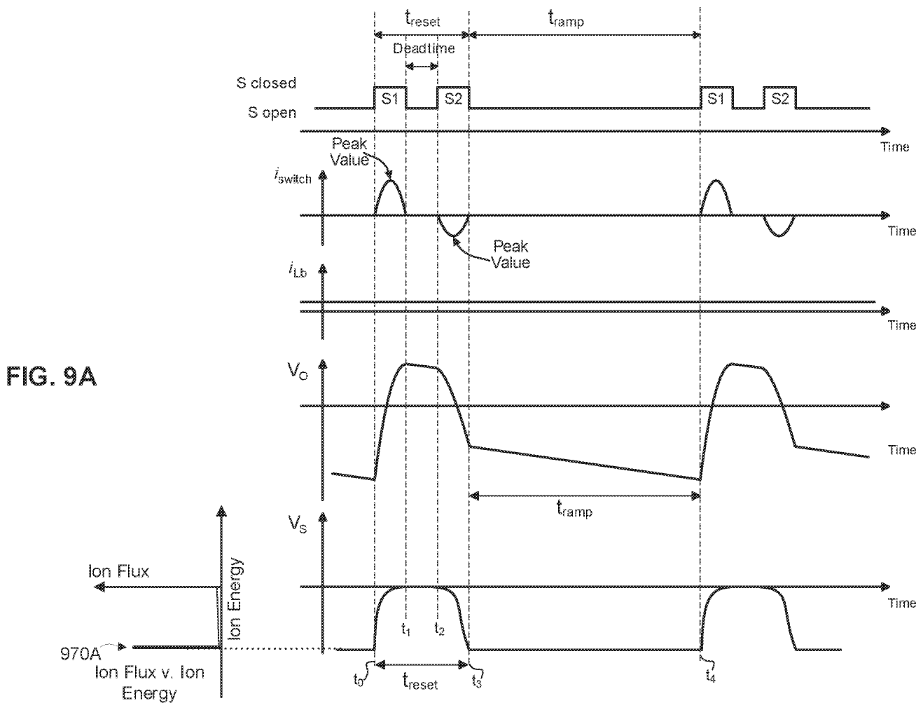

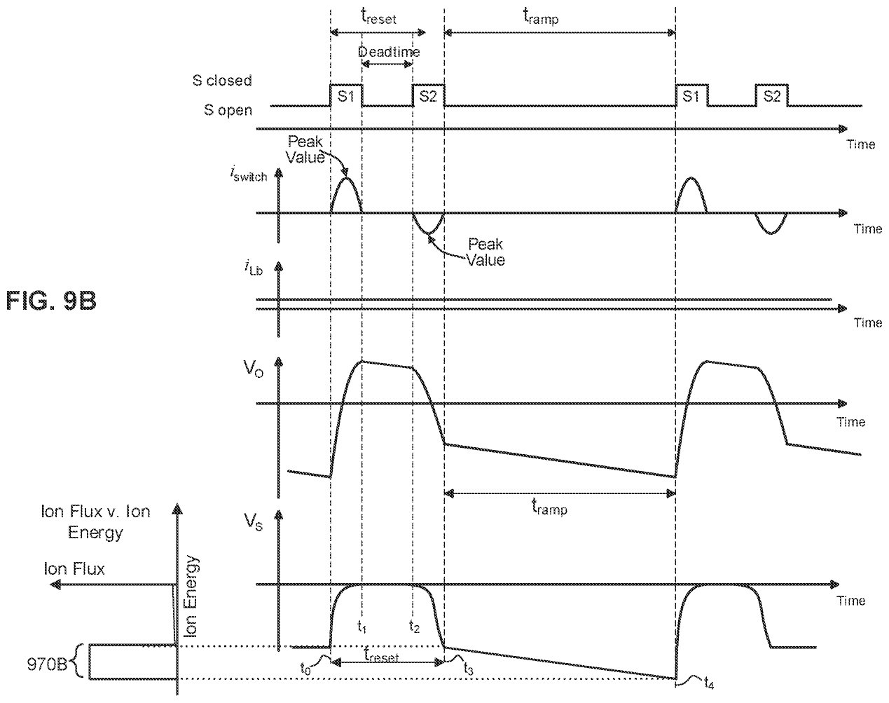

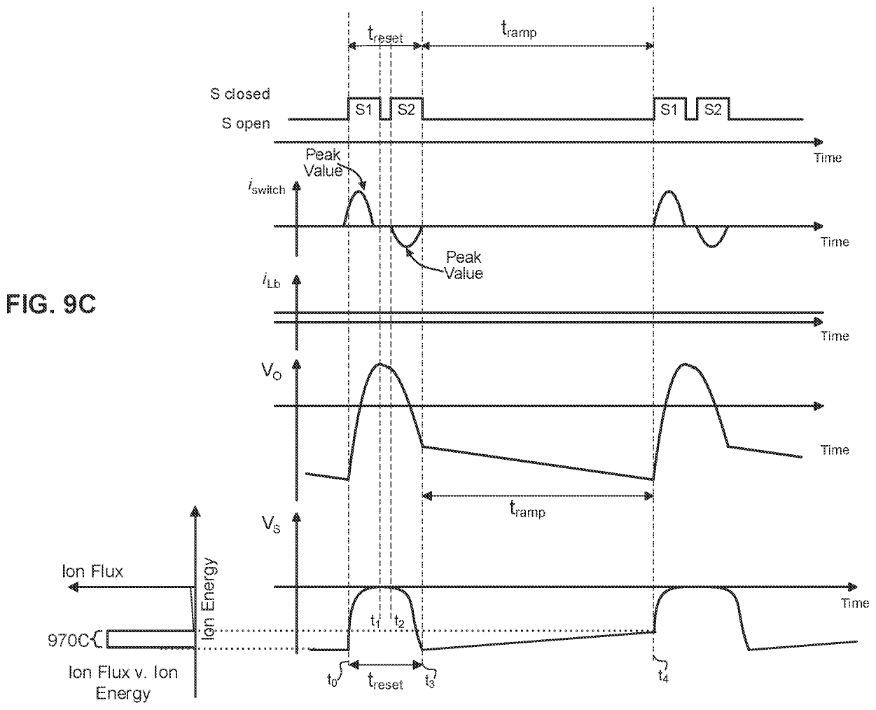

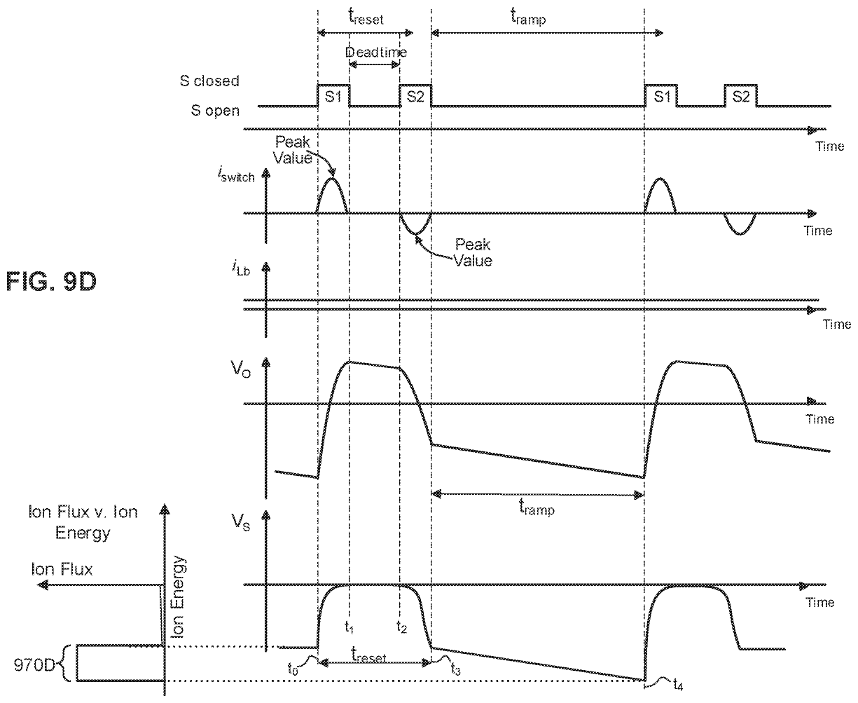

While referring to FIGS. 4A to 4D simultaneous reference is made to FIG. 5, which is a flowchart depicting a method that may be traversed in connection with embodiments disclosed herein. In addition, brief reference is also made to FIGS. 9A-9D, which each includes a collection of graphs depicting voltages and currents associated with operation of the bias supply 208. As shown, a first node 422 of the bidirectional switch 220 is coupled to the output 210 of the bias supply 208 via a first inductor, L1 (Block 502), and a first node 424 of a second inductor, Lb, is coupled to either a first node 426 of the first inductor, L1, or a second node 428 of the first inductor, L1 (Block 504). In the bias supplies 408A, 408C, and 408D of FIGS. 4A, 4C, and 4D, respectively, the first node 424 of the second inductor, Lb, is coupled to the second node 428 of the first inductor, L1. And in the bias supply 408B of FIG. 4B, the first node 424 of the second inductor, Lb, is coupled to the first node 426 of the first inductor, L1. It should be recognized that, in other variations of the implementations depicted in FIGS. 4C and 4D, the first node 424 of the second inductor, Lb, may be coupled to the first node 426 of the first inductor, L1.

In addition, a voltage source, Vb, is connected between the second node 432 of the second inductor, Lb, and the second node 430 of the bidirectional switch 220 (Block 506). And either a negative terminal 434 of the voltage source, Vb, or a positive terminal 436 of the voltage source, Vb, is coupled to the return node 212 (Block 508). In FIGS. 4A, 4B, and 4D the positive terminal 436 of the voltage source, Vb, is coupled to the return node 212, and in FIG. 4C, the negative terminal 434 of the voltage source, Vb, is coupled to the return node 212. The voltage source, Vb, may be an adjustable voltage source known to those of skill in the art that may be adjusted to control ion energy as discussed further herein.

In example bias supply 408D, there is an additional offset voltage source, Vb2, that adds a DC compensation voltage, which may be used to adjust a chucking force applied by an electrostatic chuck within the plasma processing chamber 101. In some modes of operation, the total voltage applied by Vb1 and Vb2 is set to a constant value so that the voltage applied by Vb1 is decreased when the voltage applied by Vb2 is increased.

As shown in FIGS. 5 and 9A-9D, a direction of current, i_{switch}, through the bidirectional switch 220 is controlled and a voltage is applied by a voltage source, Vb, to the output node 210 via the inductor(s), Lb to cause an application of the periodic voltage between the output node 210 and the return node 212 (Block 510). More specifically, the current, i_{switch}, through the bidirectional switch 220 is controlled over a full current cycle, which comprises a first half current cycle and a second half current cycle. The first half current cycle comprises positive current flow, starting from zero current at time t₀, that increases to a positive peak value and then decreases back to zero at a time t₁, and the second half current cycle comprises negative current flow, starting from zero current at a time t₂, that increases to a negative peak value and then decreases back to zero current at a time t₃. As shown in FIGS. 9A-9D, after time t₃, i_{switch} is substantially zero, and the supply voltage Vb (applied to the output node 210 via the inductor(s), Lb), discharges the output, creating a linear ramp portion of the periodic voltage, Vo, between t₃ and t₄ at the output node 210, which affects a bias of the workpiece 103. As shown by the substantially constant sheath voltage, Vs, between t₃ and t₄ in FIGS. 9A-9D, the linear ramp portion may maintain a negative bias of the workpiece 103. At t₄, a cycle of the periodic voltage, Vo, starts to repeat again when the bidirectional switch is controlled to allow the current, i_{switch}, through the bidirectional switch 220 to flow again.

In addition, a voltage of the voltage source, Vb, and/or a timing of conduction of the bidirectional switch 220 may be controlled to achieve a desired waveform of an electrode 104 of the plasma load, and hence, the sheath voltage, Vs, at a surface of the workpiece 103 (Block 512). As discussed further herein with reference to FIGS. 9A-11B for example, the timing of the conduction of the bidirectional switch 220 may be controlled to adjust the deadtime, tᵣₐₘₚ, and/or the output period between t₀ and t₄.

Referring next to FIG. 6A, shown is another example bias supply 608A that may be used to implement the bias supply 208. As shown, a transformer 644 is used to apply power to the output node 210 of the bias supply. The transformer 644 includes a primary winding (represented by Llp and Lp) and a secondary winding (represented by Lls and Ls). A first node 680 of the primary winding of the transformer 644 is coupled to the first node 422 of the bidirectional switch 220. A first node 682 of the secondary winding of the transformer 644 is coupled to the output node 210. And a second node 684 of the secondary winding of the transformer 644 is coupled to a return node 612 on the secondary side of the transformer 644. The voltage source, Vb, is coupled between the second node 430 of the bidirectional switch 220 and a second node 686 of the primary winding of the transformer 644.

Referring to FIG. 6B, shown is another exemplary bias supply 608B to apply a periodic voltage function. As shown, the bias supply 608B is the same as the bias supply 608A except the negative terminal 434 of the voltage source, Vb, is connected to the return node 212 and the positive terminal 436 of the voltage source, Vb, is connected to the second node 430 of the bidirectional switch 220.

The bias supplies 608C and 608D, shown in FIGS. 6C and 6D, respectively, are the same as the bias supplies 608A and 608B shown in FIGS. 6A and 6B except that an offset-voltage-source, Voffset, is coupled between the second node 684 of the secondary winding of the transformer 644 and the return node 212. More specifically, a positive terminal of the offset-voltage-source, Voffset, is coupled to the return node 212 and a negative terminal offset-voltage-source, Voffset, is coupled to the second node 684 of the transformer 644.

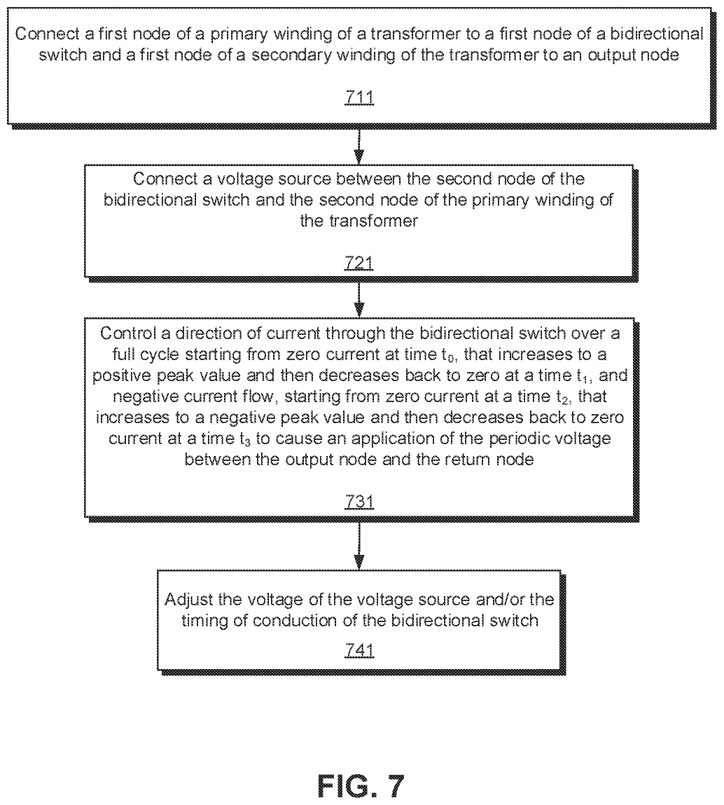

FIG. 7 is another flow chart depicting a method that may be traversed in connection with the bias supplies 608A, 608B, 608C, and 608D. While referring to FIG. 7 simultaneous reference is made to FIGS. 6A-6C and FIGS. 9A-9D. As shown, the method includes coupling a first node 680 of a primary winding of the transformer 644 to the first node 422 of the bidirectional switch 220 and the first node of the secondary winding of the transformer 644 to the output node 210 (Block 711). In addition, the method includes coupling the voltage source, Vb, between the second node 430 of the bidirectional switch and the second node 686 of the primary winding of the transformer 644 (Block 721).

In operation, a direction of current through the bidirectional switch 220 is controlled over a full current cycle, which comprises a first half current cycle and a second half current cycle. The first half current cycle comprises positive current flow, starting from zero current at time t₀, that increases to a positive peak value and then decreases back to zero at a time t1, and the second half current cycle comprises negative current flow, starting from zero current at a time t₂, that increases to a negative peak value and then decreases back to zero current at a time t₃ to cause an application of the periodic voltage between the output node and the return node (Block 731). In addition, a voltage of the voltage source, Vb, and/or a timing of conduction of the bidirectional switch 220 may be controlled to achieve a desired waveform of an electrode 104 of the plasma load, and hence, the voltage, Vs, at a surface of the workpiece 103 (Block 741).

Referring next to FIGS. 8A-8C, shown are examples of bidirectional switches 820A, 820B, and 820C that may be used to implement the bidirectional switch 220 described above. As shown, each of the bidirectional switches 820A, 820B, and 820C comprises a controller 840 coupled to a first switch, S1, and a second switch, S2, via a first driver 842A and a second driver 842B, respectively. As shown, the first driver 842A is coupled to the first switch, 51, via a first drive signal line 844A, and the second driver 842B is coupled to the second switch, S2, via a second drive signal line 844B. In addition, each of the bidirectional switches 820A, 820B, and 820C comprises a first diode D1 arranged and configured to conduct when the first switch, S1, is closed, and a second diode, D2, that is arranged and configured to conduct when the second switch, D2, is closed.

In many implementations, the first switch, S1, and/or the second switch, S2, are realized by field-effect switches such as metal-oxide semiconductor field-effect transistors (MOSFETS), and in some implementations, the first switch, S1, and the second switch, S2, are realized by silicon carbide metal-oxide semiconductor field-effect transistors (SiC MOSFETs) or gallium nitride metal-oxide semiconductor field-effect transistors (GaN MOSFETs). As another example, the first switch, S1, and/or the second switch, S2 may be realized by an insulated gate bipolar transistor (IGBT). In these implementations, the first driver 842A and the second driver 842B may be electrical drivers known in the art that are configured to apply power signals to the first switch, S1, and the second switch, S2 responsive to signals from the controller 840. It is also contemplated that the controller 840 may be capable for apply a sufficient level of power so that the first driver 842A and the second driver 842B may be omitted. It is also contemplated that the first drive signal line 844A a second drive signal line 844B may be optical lines to convey optical switching signals. And the first switch, S1, and the second switch, S2, may switch is response to optical signals and/or optical signals that are converted to electrical drive signals.

The controller 840 is depicted as a part of the bidirectional switch 820A, 820B, 820C, but it should be recognized that this is not required and that the controller 840 may be may external to the bidirectional switch 820A, 820B, 820C and/or the controller 840 may be distributed so that a portion of the controller 840 is implemented as a portion of the bidirectional switch 820A, 820B, 820C and one or more other portions of the controller 840 are implemented within the bias supply 208 and/or external to the bias supply 208.

In the variation depicted in FIG. 8A, the second diode, D2, is arranged in parallel with the first switch, S1, and the first diode, D1, is arranged in parallel with the second switch, D2. In this arrangement, the cathode of the first diode, D1, is coupled to the cathode of the second diode, D2 at a common connection 850, and the first switch, S1, and the second switch, D2, are coupled at the common connection 850 so that both the first switch, S1, and the second diode, D2, are each positioned between the common connection 850 and the first node 422 of the bidirectional switch 820A, and the second switch, S2, and the first diode, D1, are each positioned between the common connection 850 and the second node 430 of the bidirectional switch 820A. It should be recognized that the S1-D2 combination in FIG. 8A may be swapped with the 52-D1 combination so that D1 and D2 are connected at their anodes. In the implementation of FIG. 8A, the first diode, D1, may be a body diode of the second switch, D2, and the second diode, D2, may be a body diode of the first switch, S1.

In the variation depicted in FIG. 8B, a series combination of the first switch, S1, and the first diode, D1, is arranged between the first node 422 of the bidirectional switch 820B and the second node of the bidirectional switch 820B. In addition, a series combination of the second switch, S2, and the second diode, D2, is arranged between the first node 422 of the bidirectional switch 820B and the second node of the bidirectional switch 820B. As shown in FIG. 8B, the first diode, D1, is arranged between the first switch, S1, and the first node 422 of the bidirectional switch 820B with its anode coupled to the first switch, S1, and its cathode coupled to the first node 422 of the bidirectional switch 820B. The second diode, D2, is arranged between the second switch, S2, and the first node 422 of the bidirectional switch 820B with its cathode coupled to the second switch, S2, and its anode coupled to the first node 422 of the bidirectional switch 820B. In this arrangement, the cathode of the first diode, D1, is coupled to the anode of the second diode, D2 at the first node 422 of the bidirectional switch 820B. Although not depicted, it should be recognized that the position of the first switch, S1, and the position of the first diode, D1, may be swapped. Similarly, the position of the second switch, S2, and the position of the second diode, D2, may be swapped.

The bidirectional switch 820C of FIG. 8C is the same as the bidirectional switch 820B of

FIG. 8B except the bidirectional switch 820C includes at least a portion of inductor, L1, (positioned between the first diode, D1, and the first node 422 of the bidirectional switch 820C) and at least a portion of the second inductor, L2, positioned between the second diode, D2, and the first node 422 of the bidirectional switch 820C. The inductor, L1, depicted in FIG. 8C may augment or replace the inductor, L1, depicted in FIGS. 4A-4D. And inductor, L2, depicted in FIG. 8C may augment or replace the inductor, L2, depicted in FIGS. 4A-4D.

While referring to FIGS. 8A, 8B, and 8C, simultaneous reference is made to FIG. 9, which illustrates waveforms depicting electrical aspects of the bias supply 208 and plasma processing chamber 101. Shown in FIG. 9 are a switching sequence of the first switch, S1, and the second switch, S2; current Iswitch through the bidirectional switch 220; current through the second inductor i_{Lb}; voltage, Vo, at the output node 210 of the bias supply 208; and the sheath voltage, Vs (also shown in FIG. 3); and a corresponding ion energy distribution function (IEDF) depicted as ion flux versus ion energy. An aspect of the present disclosure addresses the problem of how to adjust the current, i_{Lb}, through L_{b} to be equal to the ion current Iᵢₒₙ, greater than the ion current Iᵢₒₙ, or less than the ion current Iᵢₒₙ. Another aspect of the present disclosure addresses the problem of how to adjust a level of ion energies and distribution of the ion energies in the plasma chamber.

As shown in FIGS. 9A-9D, the first switch, S1, and the second switch, S2, may be controlled so that current, I_{switch}, through the bidirectional switch 220 completes a full current cycle between times t₀ and t₃. During the first half current cycle comprising positive current flow, the current, I_{switch} is controlled from zero, at t₀, to a peak value, back to zero, at t₁. Then, during the second half current cycle, comprising negative current flow, the current, I_{switch}, is controlled from zero, at t₂, to increase, to a peak value in an opposite direction (opposite from the peak value at the first half current cycle) before decreasing back to zero at t₃. More specifically, with reference to FIGS. 8A, 8B, and 8C during a positive portion (from time t₀ to t₁) of the full current cycle, the current, I_{L1}, flows from the return node 212 through both the first diode, D1, and the first switch, S1. As shown, during the positive portion of the current cycle (when the first switch, S1, is closed and the second switch, S2, is open), the current increases to a peak positive value then decreases to zero, but the first diode D1 prevents the current from reversing direction. During a negative portion (from time t₂ to t₃) of the full current cycle, the current, flows from the output node 210 through both the second diode, D2, and the second switch, S2. As shown, during the negative portion of the current cycle, the current increases to a negative value peak value then decreases to zero, but the second diode, D2, prevents the current from reversing direction.

Referring next to FIGS. 9A, 9B, 9C, and 9D, shown are timing diagrams depicting timing of electrical aspects of the bias supplies described herein when operated with the plasma processing chamber 101. As shown, in FIGS. 9A-9D, the first switch, S1, and the second switch, S2, may be controlled with an adjustable deadtime, which is the time from t₁ to t₂ between the half current cycles (after the switch, S1, is opened from a closed position and before S2 is closed). It should be recognized that the first switch, S1, may open (or turn off) later than is depicted in FIGS. 9A-9D because the first diode, D1, prevents the current from switching direction. But generally, to minimize switching loss, the first switch, S1, is not opened before the current, I_{L1}, reaches zero at the time t₁. Similarly, the second switch, S2, may open (or turn off) later than is depicted in FIGS. 9A-9D because the second diode, D2, prevents the current from switching direction. But generally, the second switch, S2, is not opened before the current, I_{L1}, reaches zero at the time t₃.

The voltage of the voltage source, Vb, may also be adjusted to achieve a desired periodic voltage at Vₒ and a desired sheath voltage, Vs. Another controllable aspect is the reset time, tᵣₑₛₑₜ, between times t₀ and t₃, which enables control of an average per switching cycle. It should be recognized the peak value the current, i_{L1}, in a first half of the current cycle may be different than the peak value of the current, i_{L1}, in the second half of the current cycle.

As shown, the voltage, Vo, of the bias supply 208 at the output node (relative to the return node 212) is an asymmetric periodic voltage waveform wherein each cycle of the asymmetric periodic voltage waveform (from time t₀ to t₄) includes a first portion (from time t₀ to t₁) with a voltage that increases to a first voltage level, a second portion (from time t₁ to t₂) at the first voltage level (or slightly decreasing from the first voltage level), a third portion with a negative voltage swing (from time t₂ to t₃) to a second voltage level (at t₃), and a fourth portion that includes a negative voltage ramp (from t₃ to t₄) from the second voltage level. As discussed further herein, a fundamental period (from to to t₄) of the asymmetric periodic voltage waveform may be adjusted to adjust a spread of ion energies. As shown in FIGS. 9A-9D, the full current cycle occurs between times t₀ and t₃ during the first, second, and third portions of the asymmetric periodic voltage waveform. And the time between full current cycles is the time, tramp, between t3 and 4.

Beneficially, the bidirectional switch 220 provides another level of freedom in contrast to other prior art designs. Specifically, the variations of the bidirectional switch 220 disclosed herein enable control of the deadtime cycle by cycle, which means that an average of the duty cycle may be controlled, and hence, an average power per cycle may be controlled. As depicted in FIGS. 9A-9D, controlling the deadtime enables control over treset, and adjusting a ratio of tᵣₑₛₑₜ to tᵣₐₘₚ adjusts average power. And control over the average power per cycle of the asymmetrical periodic voltage waveform (from to to t₄) enables the fundamental switching frequency to be controlled (e.g., to remain below a level that affects plasma density in the plasma processing chamber 101).

Another aspect of control that may be achieved with the bias supply 208 disclosed herein is ion current compensation. More specifically, the length of the deadtime, the length of tᵣₐₘₚ, and/or the period of the periodic voltage function (between t0 and t4) may be controlled to control a level of ion current compensation. In FIG. 9A, tᵣₐₘₚ and the deadtime are established so that ion current, Iᵢₒₙ, is compensated to a point where the current, i_{Lb}, through the second inductor, Lb, equals the ion current, Iᵢₒₙ, in the plasma processing chamber 101. As shown in FIG. 9A, the sheath voltage, Vs, is substantially constant between pulses defined by the deadtime, and as a consequence, a distribution 970A of ion energies in the plasma processing chamber 101 is relatively narrow.

As shown in FIG. 9B, to overcompensate for ion current in the plasma chamber 101, the deadtime may be increased while tᵣₐₘₚ may remain the same (e.g., the same as tramp in FIG. 9A). As a consequence, the frequency of the periodic voltage waveform at Vo will be lower (as compared to the periodic voltage waveform depicted in FIG. 9A). As shown in FIG. 9B, when overcompensating for ion current, the sheath voltage Vs (and the voltage at the surface of the workpiece 103) becomes increasingly negative between times t3 and t4 (during the tᵣₐₘₚ time frame). And due to the range of sheath voltages between t3 and t4, the distribution 970B of ion energies is broader than the distribution 970A of ion energies depicted in FIG. 9A.

As shown in FIG. 9C, to undercompensate for ion current in the plasma chamber 101, the deadtime may be decreased while tᵣₐₘₚ may remain the same (e.g., the same as tramp in FIG. 9A). As a consequence, the frequency of the periodic voltage waveform at Vo will be higher (as compared to the periodic voltage waveform depicted in FIG. 9A). As shown in FIG. 9C, when undercompensating for ion current, the sheath voltage Vs (and the voltage at the surface of the workpiece 103) becomes less negative between times t3 and t4 (during the tᵣₐₘₚ time frame). And due to the range of sheath voltages between t3 and t4, the distribution 970C of ion energies is broader than the distribution 970A of ion energies depicted in FIG. 9A.

It is also possible to adjust ion current compensation by changing both the deadtime and tᵣₐₘₚ. For example, as shown in FIG. 9D, the deadtime may be lengthened and tᵣₐₘₚ may be shortened to overcompensate for ion current to achieve a desired distribution 970D of ion energies (corresponding to the range of voltage of the sheath voltage Vs between times t3 and t4). By adjusting both deadtime and tᵣₐₘₚ, the frequency of the periodic voltage waveform may be fixed if desired, but it is also possible to vary the deadtime, tᵣₐₘₚ, and the frequency of the periodic voltage waveform. It is also contemplated that the deadtime may be shortened while shortening or lengthening tᵣₐₘₚ.

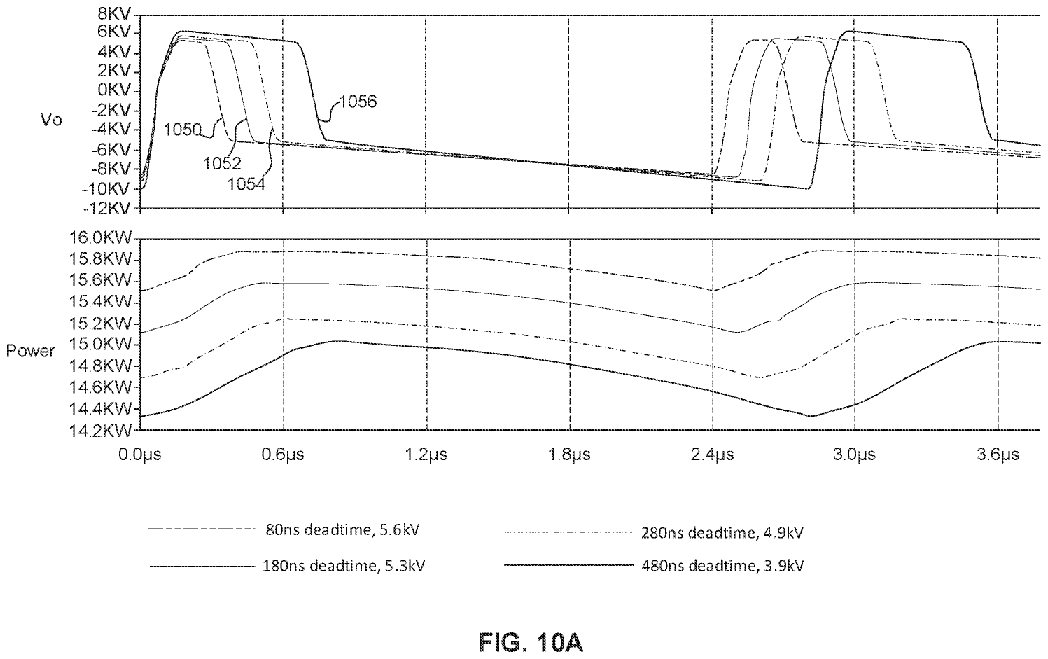

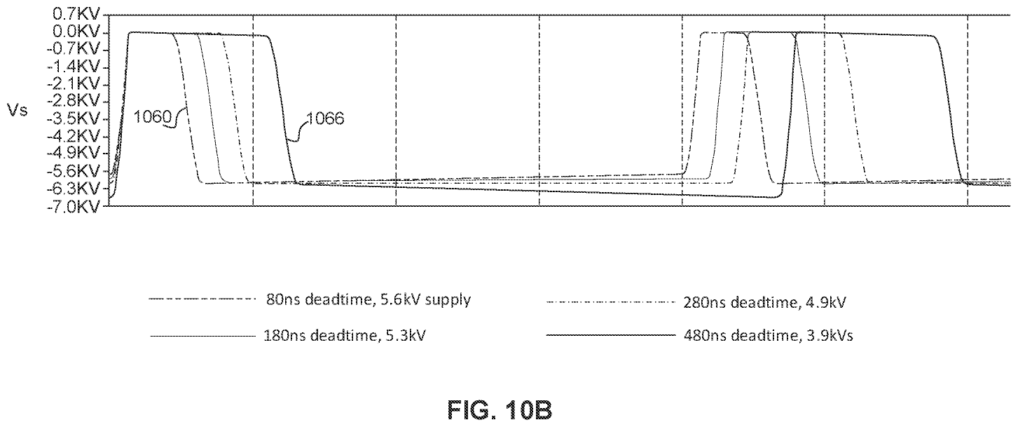

In addition to affecting ion current compensation, the deadtime and/or the voltage applied by the voltage source, Vb, may also be adjusted to change a level of power that is applied by the bias supply. Referring to FIG. 10A for example, shown are four periodic voltage waveforms at Vo: a first waveform 1050 at Vo is produced by an 80 ns deadtime and a voltage source voltage, Vb, of 5.6 kV; a second waveform 1052 is produced at Vo with a 180 ns deadtime and a source voltage, Vb, of 5.3 kV; a third waveform 1054 is produced at Vo with a 280 ns deadtime and a source voltage, Vb, of 4.9 kV; and a fourth waveform 1056 is produced at Vo with a 480 ns deadtime and a source voltage, Vb, of 3.9 kV. As shown, the time of tᵣₐₘₚ remains the same for each of the four example periodic voltage waveforms 1050, 1052, 1054, 1056. And in general, the shorter the deadtime, the higher the level of power that is applied by the bias supply 208. More specifically, the shorter the deadtime, the shorter tᵣₑₛₑₜ, and the smaller the ratio of tᵣₑₛₑₜ is to tramp, the higher the average power that is applied by the bias supply 208.

Referring next to FIG. 10B shown are four sheath voltages Vs that correspond to the four example periodic voltage waveforms 1050, 1052, 1054, 1056. As shown, a first sheath voltage 1060, corresponding to the first waveform 1050 with the shortest deadtime (among the four example periodic voltage waveforms 1050, 1052, 1054, 1056) comprises a portion that becomes less negative over time between voltage pulses, which results in an under compensation of ion current (similar to the sheath voltage described with reference to FIG. 9C). And in contrast, a fourth sheath voltage 1066, corresponding to the fourth waveform 1056, comprises a portion that becomes more negative between voltage pulses, which results in overcompensation of ion current (similar to the sheath voltage described with reference to FIG. 9B).

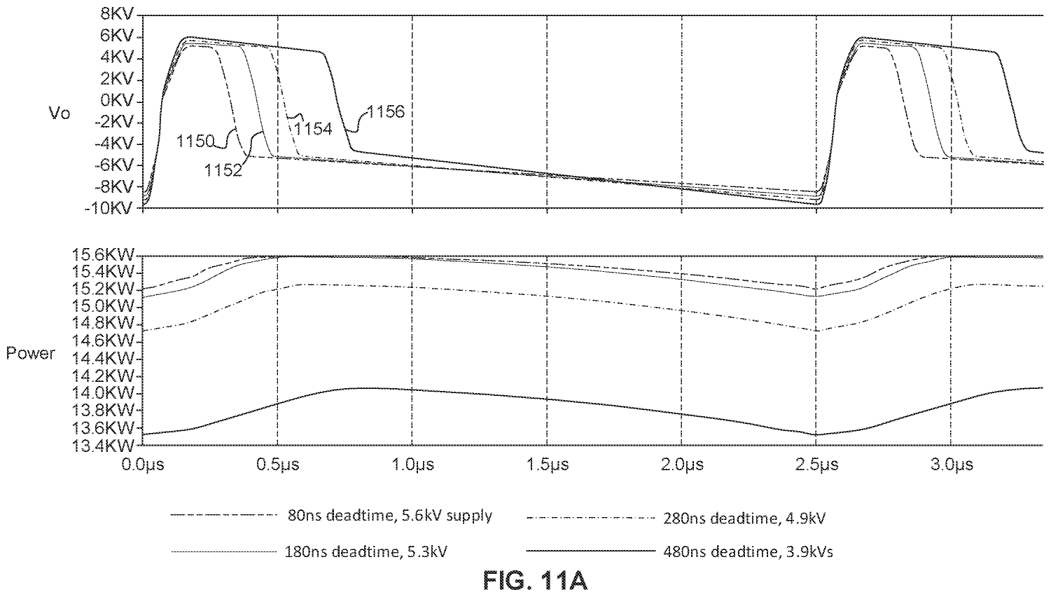

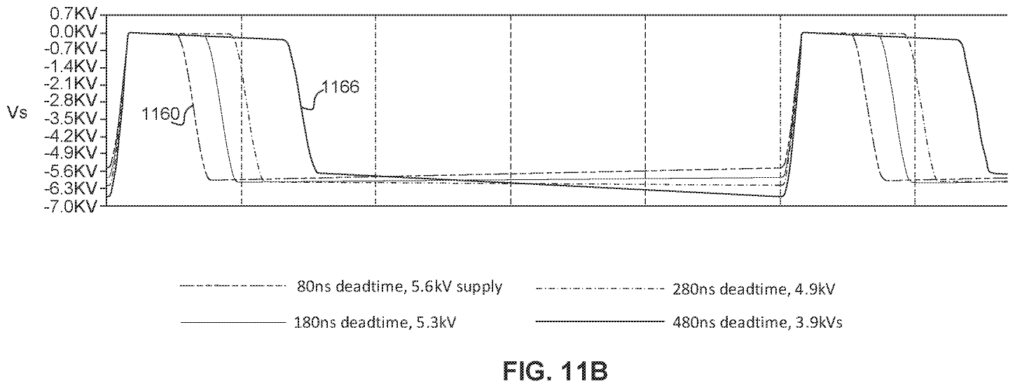

Referring to FIG. 11A, shown are four periodic voltage waveforms at Vo: a first waveform 1150 at Vo is produced by an 80 ns deadtime and a voltage source voltage, Vb, of 5.6 kV; a second waveform 1152 is produced at Vo with an 180 ns deadtime and a source voltage, Vb, of 5.3 kV; a third waveform 1154 is produced at Vo with a 280 ns deadtime and a source voltage, Vb, of 4.9 kV; and a fourth waveform 1156 is produced at Vo with a 480 ns deadtime and a source voltage, Vb, of 3.9 kV. As shown, the time of tᵣₐₘₚ changes for each of the four example periodic voltage waveforms 1150, 1152, 1154, 1156 so that the frequency of the four example periodic voltage waveforms 1150, 1152, 1154, 1156 remains the same. More specifically, as the deadtime becomes longer, tᵣₐₘₚ becomes shorter. As shown, in general, the shorter the deadtime, the higher the level of power that is applied by the bias supply 208. And in general, the shorter the deadtime, the higher the level of power that is applied by the bias supply 208. More specifically, the shorter the deadtime, the shorter treset becomes, and the smaller the ratio of tᵣₑₛₑₜ is to tᵣₐₘₚ, the higher the average power that is applied by the bias supply 208.

Referring next to FIG. 11B shown are four sheath voltages, Vs, that correspond to the four example periodic voltage waveforms 1150, 1152, 1154, 1156. As shown, a first sheath voltage 1160, corresponding to the first waveform 1150 with the shortest deadtime (among the four example periodic voltage waveforms 1150, 1152, 1154, 1156), comprises a portion that becomes less negative over time between voltage pulses, which results in an under compensation of ion current. And in contrast, a fourth sheath voltage 1166, corresponding to the fourth waveform 1156, comprises a portion that becomes more negative between voltage pulses, which results in overcompensation of ion current (similar to the sheath voltage described with reference to FIG. 9D).

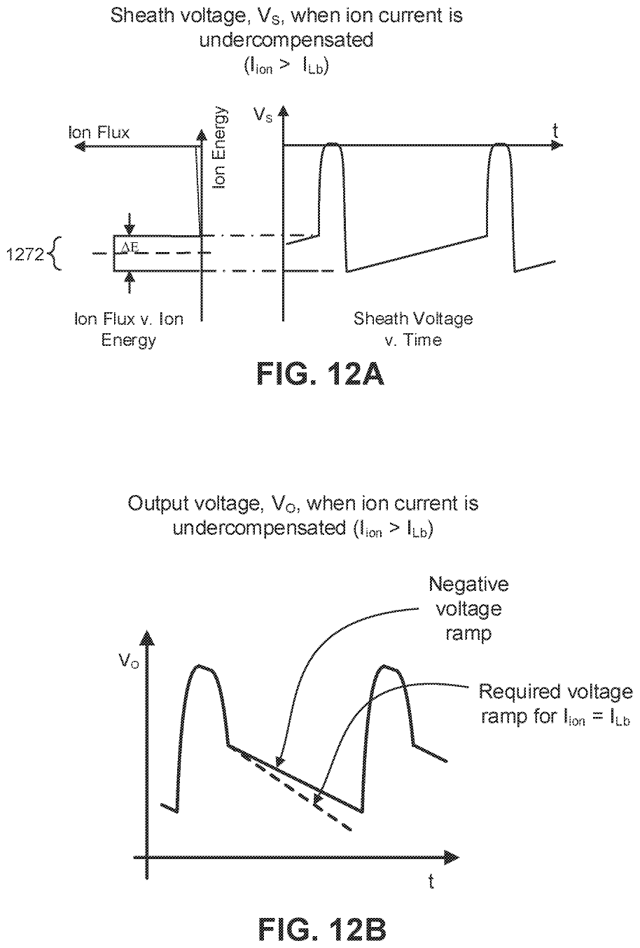

Referring to FIGS. 12A and 12B, shown are general aspects of sheath voltage, ion flux, and a periodic asymmetric voltage waveform (output by the bias supply 208) associated with under-compensated ion current. As shown in FIG. 12A, when ion current, Iᵢₒₙ, is under compensated, a sheath voltage becomes less negative in a ramp-like manner, which produces a broader distribution (also referred to as a spread) 1272 of ion energies. Shown in FIG. 12B is a periodic voltage that may be applied to a substrate support to effectuate the sheath voltage depicted in FIG. 12A. As shown, the negative ramp-like portion of the periodic voltage waveform, Vo, drops with a lower slope than the ramp-like portion of the period voltage waveform of FIG. 9A (shown as a broken line in FIG. 12B).

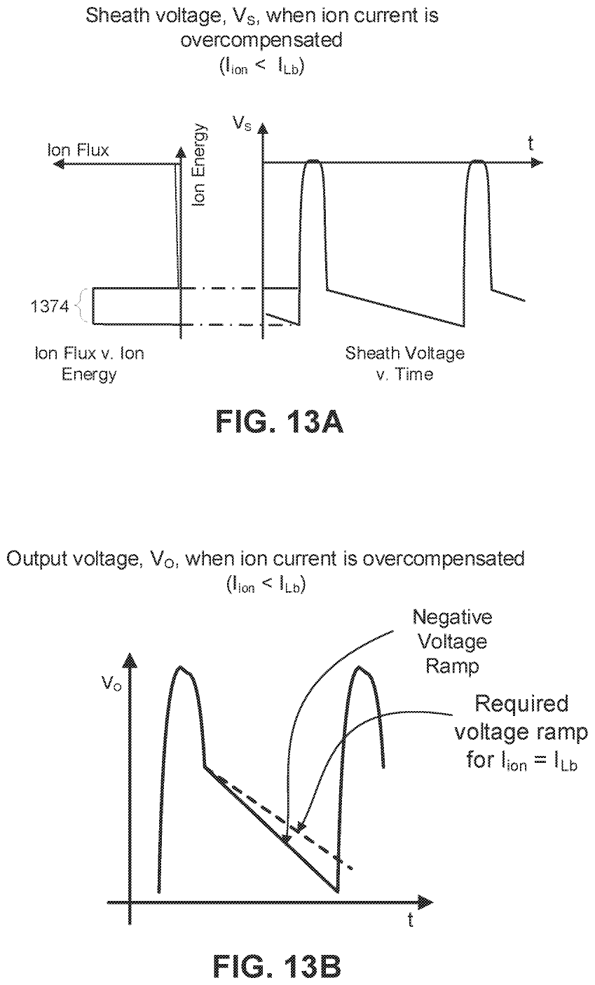

FIGS. 13A and 13B depict aspects of sheath voltage, ion flux, and a periodic asymmetric voltage waveform (output by the bias supply 208) associated with over-compensated ion current. As shown in FIG. 13A, when ion current is over compensated, a sheath voltage becomes more negative in a ramp-like manner, which also produces a broader spread 1374 of ion energies (in contrast to operation where ion current, Iᵢₒₙ, is equal to the current, i_{Lb}). As, shown in FIG. 13B, is a periodic voltage waveform, Vo, may be applied to a substrate support to effectuate the sheath voltage depicted in FIG. 13A. As shown, the negative ramp-like portion of the periodic voltage function drops at a greater rate than the ramp-like portion of the period voltage waveform of FIG. 9A that compensates for ion current (shown as a dotted line).

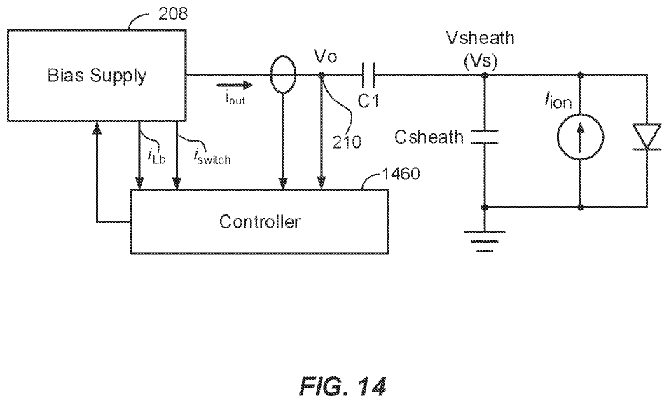

Referring to FIG. 14, shown are aspects a control system that may be used in connection with embodiments herein. Also shown are representations of a sheath capacitance (Csheath) and a capacitance C1 that represents the inherent capacitance of components associated with the plasma processing chamber 101, which may include insulation, the workpiece, substrate support, and an echuck.

As shown, current and/or voltage may be measured by the controller 1460 to indirectly monitor aspects (e.g., voltage, current, and/or phase) of the power applied to the output node 210 of the bias supply 208 and/or one or more characteristics of an environment of the plasma processing chamber 101. An exemplary characteristic of the environment of the plasma processing chamber 101 may be sheath capacitance (Csheath), which may be calculated using a measured output voltage, Vo.

As shown, the current through the bidirectional switch 220, the current iₒᵤₜ at the output, and/or the current through the second inductor, Lb, may be monitored and used as feedback. In addition, the voltage, Vo, at the output node 210 of the bias supply may be monitored and used as feedback.

The monitoring may be performed in advance of processing the workpiece 103 to obtain data (e.g., about sheath capacitance and/or other characteristics of the environment of the plasma processing chamber) that is stored, and then the data is utilized to adjust the periodic waveform, Vo (e.g., in a feed-forward manner). The monitoring may also be performed during plasma processing, and the voltage source, Vb, tᵣₐₘₚ, and/or deadtime may be adjusted using real-time feedback using, for example, voltage and/or current measurements as shown in FIG. 14. In addition, a negative voltage swing (from time t₂ to t₃) of the third portion of the periodic voltage waveform may be controlled to establish a desired sheath voltage, Vs. The controller 840 described with reference to FIGS. 4A-4D may be implemented as a part of the controller 1460 or the controller 840 may be implemented separately from the controller 1460, but it is certainly contemplated that controller 840 and controller 1460 may communicate to control the bias supply 208.

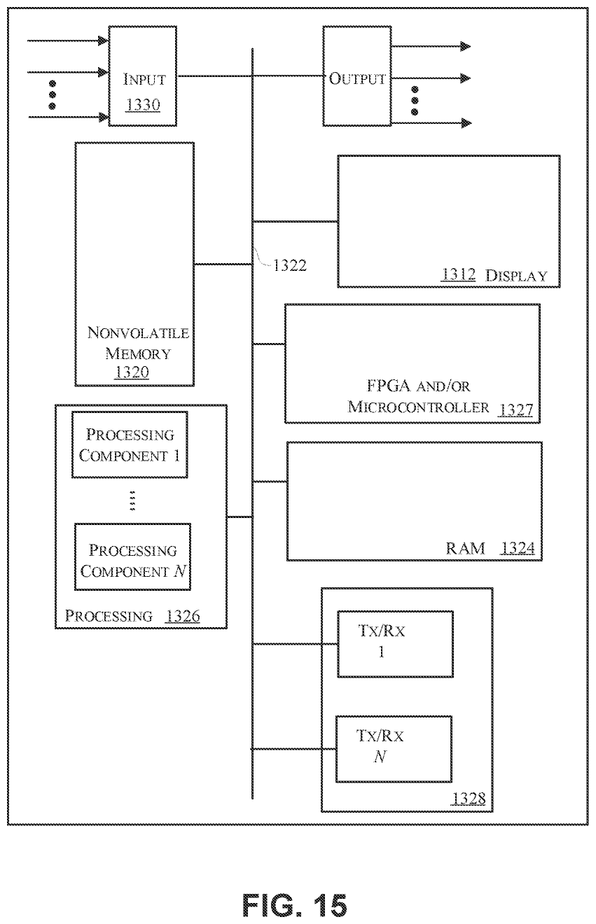

The methods described in connection with the embodiments disclosed herein may be embodied directly in hardware, in processor-executable code encoded in a non-transitory tangible processor readable storage medium, or in a combination of the two. Referring to FIG. 15 for example, shown is a block diagram depicting physical components that may be utilized to realize control aspects disclosed herein. As shown, in this embodiment a display 1312 and nonvolatile memory 1320 are coupled to a bus 1322 that is also coupled to random access memory (“RAM”) 1324, a processing portion (which includes N processing components) 1326, a field programmable gate array (FPGA) 1327, and a transceiver component 1328 that includes N transceivers. Although the components depicted in FIG. 15 represent physical components, FIG. 15 is not intended to be a detailed hardware diagram; thus, many of the components depicted in FIG. 15 may be realized by common constructs or distributed among additional physical components. Moreover, it is contemplated that other existing and yet-to-be developed physical components and architectures may be utilized to implement the functional components described with reference to FIG. 15.

This display 1312 generally operates to provide a user interface for a user, and in several implementations, the display is realized by a touchscreen display. In general, the nonvolatile memory 1320 is non-transitory, tangible processor readable storage medium and functions to store (e.g., persistently store) data and processor readable instructions (including executable code that is associated with effectuating the methods described herein). In some embodiments for example, the nonvolatile memory 1320 includes bootloader code, operating system code, file system code, and non-transitory processor-executable code to facilitate the execution of a method of biasing a substrate with the single controlled switch.

In many implementations, the nonvolatile memory 1320 is realized by flash memory (e.g., NAND or ONENAND memory), but it is contemplated that other memory types may be utilized as well. Although it may be possible to execute the code from the nonvolatile memory 1320, the executable code in the nonvolatile memory is typically loaded into RAM 1324 and executed by one or more of the N processing components in the processing portion 1326.

The N processing components in connection with RAM 1324 generally operate to execute the instructions stored in nonvolatile memory 1320 to enable execution of the algorithms and functions disclosed herein. It should be recognized that several algorithms are disclosed herein, but some of these algorithms are not represented in flowcharts. Processor-executable code to effectuate methods described herein may be persistently stored in nonvolatile memory 1320 and executed by the N processing components in connection with RAM 1324. As one of ordinarily skill in the art will appreciate, the processing portion 1326 may include a video processor, digital signal processor (DSP), micro-controller, graphics processing unit (GPU), or other hardware processing components or combinations of hardware and software processing components (e.g., an FPGA or an FPGA including digital logic processing portions).

In addition, or in the alternative, non-transitory FPGA-configuration-instructions may be persistently stored in nonvolatile memory 1320 and accessed (e.g., during boot up) to configure a field programmable gate array (FPGA) to implement the algorithms disclosed herein (e.g., including, but not limited t₀, the algorithms described with reference to FIGS. 5 and 7).

The input component 1330 may receive signals (e.g., signals indicative of current and voltage obtained at the output of the disclosed bias supplies). In addition, the input component 1330 may receive phase information and/or a synchronization signal between bias supplies 108 and source generator 112 that are indicative of one or more aspects of an environment within a plasma processing chamber 101 and/or synchronized control between a source generator and the single switch bias supply. The signals received at the input component may include, for example, synchronization signals, power control signals to the various generators and power supply units, or control signals from a user interface. Those of ordinary skill in the art will readily appreciate that any of a variety of types of sensors such as, without limitation, directional couplers and voltage-current (VI) sensors, may be used to sample power parameters, such as voltage and current, and that the signals indicative of the power parameters may be generated in the analog domain and converted to the digital domain.

The output component generally operates to provide one or more analog or digital signals to effectuate the opening and closing of the first switch, S1 and the second switch, S2. The output component may also control of the voltage sources described herein.

The depicted transceiver component 1328 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

As will be appreciated by one skilled in the art, aspects of the present disclosure may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable medium(s) having computer readable program code embodied thereon.

As used herein, the recitation of “at least one of A, B or C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A bias supply to apply a periodic voltage comprising:
an output node;
a return node;
a bidirectional switch configured to enable bidirectional control of current between a first node of the bidirectional switch and a second node of the bidirectional switch;
a power section coupled to the output node, the return node, and the first and second nodes of the bidirectional switch; and
a controller configured to control a direction of current through the bidirectional switch over a full current cycle, the full current cycle comprising a first half current cycle and a second half current cycle, the first half current cycle comprising positive current flow, starting from zero current at time t₀, that increases to a positive peak value and then decreases back to zero at a time t₁, the second half current cycle comprises negative current flow, starting from zero current at a time t₂, that increases to a negative peak value and then decreases back to zero current at a time t₃ to cause an application of the periodic voltage between the output node and the return node.

2. The bias supply of claim 1, wherein the power section comprises:
a first inductor coupled between the first node of the bidirectional switch and the output node;
a first node of a second inductor coupled to the output node; and
a voltage source coupled to a second node of the second inductor and the return node.

3. The bias supply of claim 1, wherein the controller is configured to enable control of a deadtime between t₁ and t₂ to enable control of an average power.

4. The bias supply of claim 1, wherein the bidirectional switch comprises:
a first switch coupled to a first diode; and
a second switch coupled to a second diode;
wherein the controller is configured to:
close the first switch at the time t₀, to enable the positive current flow through the first switch and the first diode to complete the first half current cycle; and
open the first switch and then close the second switch to enable the negative current to flow through the second switch and the second diode to complete the second half current cycle.

5. The bias supply of claim 4, wherein the controller is configured to enable control of a deadtime between t₁ and t₂ to enable control of an average power.

6. The bias supply of claim 2, wherein the second node of the second inductor is coupled to the return node.

7. The bias supply of claim 2, wherein the voltage source is the only voltage source in the bias supply.

8. The bias supply of claim 2, comprising a second voltage source, and wherein the voltage source is coupled to the second node of the bidirectional switch via the second voltage source.

9. The bias supply of claim 2, wherein at least a portion of the first inductor is positioned inside of the bidirectional switch.

10. The bias supply of claim 1, wherein the power section comprises:
a transformer, a first node of a primary winding of the transformer coupled to a first node of the bidirectional switch, a first node of a secondary winding of the transformer coupled to the output node, and a second node of the secondary winding of the transformer coupled to the return node; and
a voltage source coupled between a second node of the bidirectional switch and a second node of the primary winding of the transformer.

11. The bias supply of claim 10, comprising an offset voltage source, a second node of the secondary winding of the transformer is coupled to the return node via the offset voltage source.

12. A plasma processing system comprising:
a plasma chamber including:
a volume to contain a plasma;
an input node;
a return node; and
a bias supply including:
a bidirectional switch configured to enable bidirectional control of current between a first node of the bidirectional switch and a second node of the bidirectional switch; and
means for providing and controlling current through the bidirectional switch over a full current cycle, the full current cycle comprising a first half current cycle and a second half current cycle, the first half current cycle comprising positive current flow, starting from zero current at time t₀, that increases to a positive peak value and then decreases back to zero at a time t₁, the second half current cycle comprises negative current flow, starting from zero current at a time t₂, that increases to a negative peak value and then decreases back to zero current at a time t₃ to cause an application of a periodic voltage between the input node and the return node.

13. The system of claim 12 comprising:
means for adjusting a time between t₁ and t₂ to adjust average power.

14. The system of claim 12 comprising an adjustable voltage source to adjust ion energy.

15. The system of claim 12 comprising means for adjusting at least one of a time between the full current cycles, a time between half current cycles, or a fundamental period of the periodic voltage to adjust a spread of ion energies.

16. A non-transitory, tangible processor readable storage medium, encoded with processor readable instructions to control a bidirectional switch of a bias supply, the instructions comprising instructions to:
provide current through the bidirectional switch; and
control the current through the bidirectional switch over a full current cycle to cause an application of a periodic voltage between an output node and a return node of the bias supply, the full current cycle comprising a first half current cycle and a second half current cycle, the first half current cycle comprising positive current flow, starting from zero current at time t₀, that increases to a positive peak value and then decreases back to zero at a time t₁, the second half current cycle comprises negative current flow, starting from zero current at a time t₂, that increases to a negative peak value and then decreases back to zero current at a time t₃.

17. The non-transitory, tangible processor readable storage medium of claim 16 comprising instructions to control an adjustable voltage source of the bias supply to adjust ion energy.

18. The non-transitory, tangible processor readable storage medium of claim 16 comprising instructions to adjust at least one of a time between the full current cycles, a time between the half current cycles, or a fundamental period of the periodic voltage to adjust a spread of ion energies.
